(19) United States
(12) Patent Application Publication
(10) Pub. No.: US 2025/0374505 A1
(43) Pub. Date: Dec. 4, 2025

(54) MEMORY DEVICES AND METHODS FOR MANUFACTURING THE SAME

(71) Applicant: Taiwan Semiconductor Manufacturing Company, Ltd., Hsinchu (TW)

(72) Inventors: Hidehiro Fujiwara, New Taipei City (TW); Yuichiro Ishii, Hsinchu (TW); Makoto Yabuuchi, Yilan County (TW); Masaya Hamada, Hsinchu (TW); Yi-Hsin Nien, Hsinchu City (TW); Chih-Yu Lin, Hsinchu City (TW); Yen-Huei Chen, Hsinchu City (TW); Yih Wang, Hsinchu (TW)

(73) Assignee: Taiwan Semiconductor Manufacturing Company, Ltd., Hsinchu (TW)

(21) Appl. No.: 18/827,967

(22) Filed: Sep. 9, 2024

Related U.S. Application Data
(60) Provisional application No. 63/655,370, filed on Jun. 3, 2024.

(51) Int. Cl. H10B 10/00

(52) U.S. Cl. CPC H10B 10/125

(57) ABSTRACT

A memory device includes a storage element formed of a first inverter and a second inverter cross-coupled to each other, a first transistor having a first conductive type, and connected between a first bit line and a first storage node of the storage element; a second transistor having the first conductive type, and connected between a second bit line and a second storage node of the storage element; and a third transistor having a second conductive type opposite to the first conductive type, and connected between the first storage node and a third bit line.

### CROSS-REFERENCE TO RELATED APPLICATION

This application claims priority to and the benefit of U.S. Provisional Application No. 63/655,370, filed Jun. 3, 2024, entitled “BITCELL FOR IMPROVED NBTI TOLERANCE,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device that includes a number of memory cells, accordance with some embodiments.

FIG. 2 illustrates a circuit diagram of one implementation of the memory cell of FIG. 1, accordance with some embodiments.

FIG. 3 illustrates a layout that can form the memory cell shown in FIG. 2, accordance with some embodiments.

FIG. 4 illustrates a cross-sectional view of an implementation of the memory cell shown in FIG. 2, accordance with some embodiments.

FIG. 5 illustrates waveforms of signals when operating the memory cell of FIG. 2, accordance with some embodiments.

FIG. 6 illustrates a circuit diagram of another implementation of the memory cell of FIG. 1, accordance with some embodiments.

FIG. 7 illustrates a layout that can form the memory cell shown in FIG. 6, accordance with some embodiments.

FIG. 8 illustrates a circuit diagram of yet another implementation of the memory cell of FIG. 1, accordance with some embodiments.

FIG. 9 illustrates a layout that can form the memory cell shown in FIG. 8, accordance with some embodiments.

FIG. 10 illustrates waveforms of signals when operating the memory cell of FIG. 8, accordance with some embodiments.

FIG. 11 illustrates a circuit diagram of yet another implementation of the memory cell of FIG. 1, accordance with some embodiments.

FIG. 12 illustrates a layout that can form the memory cell shown in FIG. 11, accordance with some embodiments.

FIG. 13 illustrate an example flow chart of a method for fabricating a memory device configured in a GAA transistor or FinFET structure, in accordance with some embodiments.

FIG. 14 illustrate an example flow chart of a method for fabricating a memory device configured in a CFET structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuits commonly include Static Random Access Memory (SRAM) circuits to provide on-chip data storage. An SRAM circuit is typically configured to meet specific design requirements associated with the surrounding circuitry attached to the SRAM circuit. One common type of SRAM circuit provides one port for either read or write access to data stored within the SRAM circuit. The address inputs to such a circuit are typically shared for both read and write access. Another common type of SRAM circuit, referred to as a two-port SRAM circuit, provides two ports for accessing data stored within the SRAM circuit. Two-port SRAM circuits usually restrict all read accesses to one port and all write accesses to the second port. Each port of a two-port SRAM circuit is typically capable of asynchronous, independent access to data stored within the SRAM circuit, allowing the two-port SRAM circuit to be incorporated in a range of different applications with different usage models.

The two-port SRAM circuit allows designers to achieve system performance levels that are generally higher than those possible using only one-port SRAM circuits. However, the two-port SRAM circuit commonly suffers from aging of the SRAM circuit, sometimes referred to as a Negative Bias Temperature Instability (NBTI) effect. In accordance with aging of an SRAM circuit (or its transistor components), the absolute value of a threshold voltage of the p-type transistor increases, which causes the transistors harder to turn on resulting in lower conduction current. This consequently leads to various issues for the existing two-port SRAM circuits. For example, the existing two-port (or multi-port) SRAM cell commonly includes a p-type pass-gate transistor operatively coupled between one of the storage nodes of the SRAM cell and a read port (e.g., a read bit line). Largely due to the NBTI effect present on at least one of the p-type pull-up transistors of the SRAM cell, the existing SRAM cells frequently exhibit a worsened static noise margin with an increasing threshold voltage shift on the p-type pull-up transistor(s). Thus, the existing two-port SRAM circuits have not been entirely satisfactory in certain aspects.

The present disclosure provides various embodiments of a memory device that includes a plural number of memory cells, each of which is implemented as a multi-port SRAM cell that can be relatively or almost free from the NBTI effect even with aging of the disclosed memory device. In one aspect, the disclosed SRAM cell consists of seven transistors, four of which operatively serve as a pair of cross-coupled inverters, two of which operatively serve as write pass-gate transistors, and one of which operatively serves as a read pass-gate transistor. In some embodiments, the write pass-gate transistors are each implemented as a p-type transistor, and the read pass-gate transistor is implemented as an n-type transistor. In another aspect, the disclosed SRAM cell consists of eight transistors, four of which operatively serve as a pair of cross-coupled inverters, two of which operatively serve as write pass-gate transistors, and two of which operatively serves as read pass-gate transistors. The cross-coupled inverters (an input of a first one of the inverters connected to an output of a second one of the inverters and an output of the first inverter connected to an input of the second inverter) can latch a data bit in storage nodes of the cross-coupled inverters. In some embodiments, the write pass-gate transistors, coupling the storage nodes to respective write ports (e.g., write bit lines), are each implemented as a p-type transistor, and the read pass-gate transistors, coupling the storage nodes to one or more read ports (e.g., read bit lines), are each implemented as an n-type transistor. By using the n-type transistor, which is relatively immune from the NBTI effect when compared to the p-type transistors, to couple the storage node to a read port, the disclosed SRAM cell advantageously shows a static noise margin with significantly reduced dependence on the aging of the memory device (e.g., p-type pull-up transistors forming the cross-coupled inverters).

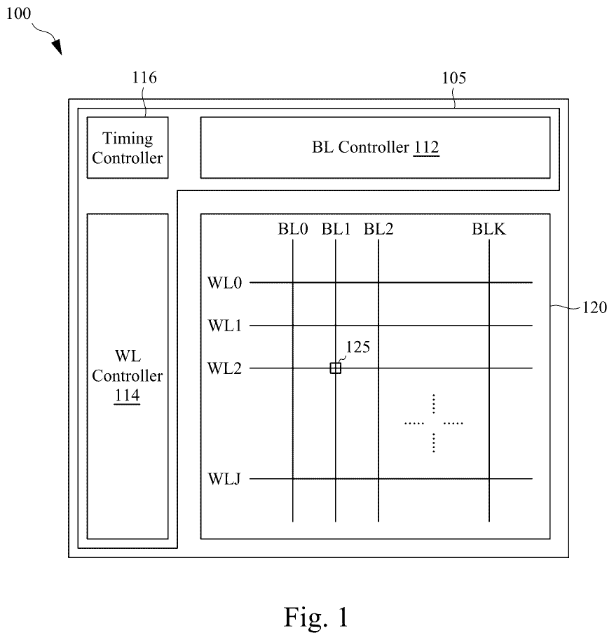

FIG. 1 illustrates a block diagram of a memory system, circuit, or device 100, in accordance with various embodiments. The memory device 100 is implemented as an integrated circuit. As shown in the illustrated example of FIG. 1, the memory device 100 includes a memory controller 105 and a memory array 120. The memory array 120 may include a number of storage circuits, memory cells, memory bits, or bit cells 125 arranged in two-dimensional or three-dimensional arrays. Each of the memory cells 125 is accessible through a plural number of access lines.

For example, each of the memory cells 125 may be connected to at least a corresponding word line WL and a corresponding pair of bit lines BL. Each of the word lines WL and bit lines BL may include any conductive (e.g., metal) material. For example, each of the word lines WL and bit lines BL can be implemented as one or more metal lines. The memory controller 105 may write data to or read data from the memory array 120 according to electrical signals through word lines WL and bit lines BL. In other embodiments, the memory system 100 includes more, fewer, or different components than shown in FIG. 1, while remaining within the scope of the present disclosure.

The memory array 120 is a hardware component that stores data. In various embodiments, the memory array 120 is embodied as a semiconductor memory device. The memory array 120 includes a number of storage circuits or memory cells 125, each of which is configured to store at least one data bit. In some embodiments, the memory array 120 includes word lines WL₀, WL₁ . . . WL_{J}, each extending in a first direction and bit lines BL₀, BL₁ . . . BL_{K}, each extending in a second direction. The word lines WL and the bit lines BL may be conductive metals or conductive rails. Each memory cell 125 is connected to at least one corresponding word line WL and at least one corresponding bit line BL (e.g., each memory cell 125 formed at an intersection of the corresponding word line WL and the corresponding bit line BL), and can be operated according to voltages or currents through the corresponding word line WL and the corresponding bit line BL. Each memory cell 125 may be a Static Random-Access Memory (SRAM) cell. In one embodiment, the memory cell 125 can be implemented as a seven-transistor (7T) SRAM cell or otherwise two-port SRAM cell. In another embodiment, the memory cell 125 can be implemented as an eight-transistor (8T) SRAM cell or otherwise three-port SRAM cell. However, it should be understood that the memory cell 125 can be implemented in any of various other memory configurations, while remaining within the scope of the present disclosure. In some embodiments, the memory array 120 includes additional lines (e.g., sense lines, reference lines, reference control lines, power rails, etc.).

The memory controller 105 is a hardware component that controls operations of the memory array 120. In some embodiments, the memory controller 105 includes a bit line controller 112, a word line controller 114, and a timing controller 116. In various embodiments, the word line controller 114 is a circuit that can provide a voltage or current signal through one or more word lines WL of the memory array 120. In various embodiments, the bit line controller 112 is a circuit that can provide a voltage or current signal through one or more bit lines BL of the memory array 120 and senses a voltage or current from the memory array 120 through the one or more bit lines BL. In various embodiments, the timing controller 116 is a circuit that can provide a clock signal for a read access or write access on the memory array 120. Further, the timing controller 116 can provide the word line controller 114 and the bit line controller 112 with control signals or the above-mentioned clock signals, respectively, so as to synchronize operations of the bit line controller 112 and the word line controller 114.

The bit line controller 112 may be connected to the bit lines BL of the memory array 120, and the word line controller 114 may be connected to the word lines WL of the memory array 120. In general, to write data to a memory cell 125, the word line controller 114 is configured to apply a voltage or current signal (sometimes referred to as a WL signal) to the memory cell 125 through one or more corresponding word lines WL connected to the memory cell 125, and the bit line controller 112 is configured to apply a voltage or current signal corresponding to a data bit to be stored to the memory cell 125 through one or more corresponding bit lines BL connected to the memory cell 125. To read the data bit from a memory cell 125, the word line controller 114 is configured to apply a WL signal to the memory cell 125 through the corresponding word line(s) WL connected to the memory cell 125, and the bit line controller 112 is configured to sense a voltage or current corresponding to the data bit stored by the memory cell 125 through the corresponding bit line(s) BL connected to the memory cell 125. In some other embodiments, the memory controller 105 can include more, fewer, or different components than shown in FIG. 1, while remaining within the scope of the present disclosure.

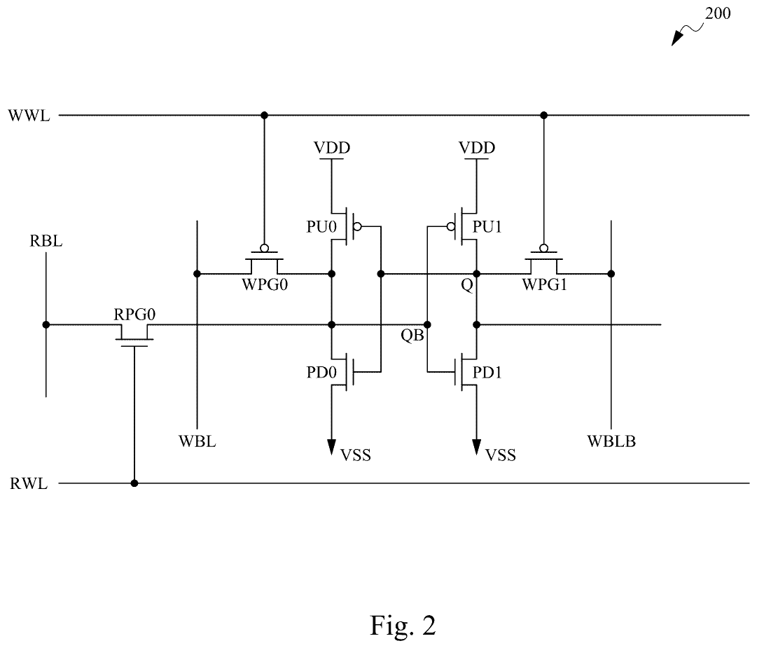

FIG. 2 illustrates an example circuit diagram 200 of one implementation of the memory cell 125 shown in FIG. 1 (hereinafter “memory cell 200”), in accordance with some embodiments. As disclosed herein, the memory cell 200 can sometimes be referred to as a 7T SRAM cell, with one read port and one write port. For example, the read port (e.g., including a read bit line RBL and a read word line RWL) may be operative in accordance with a first clock signal, and the write port (e.g., including a pair of write bit lines, WBL and WBLB, and a write word line WWL) may be operative in accordance with a second clock signal. However, it should be understood that the memory cell 200 can be implemented as any of various other multi-port SRAM cell, while remaining within the scope of the present disclosure.

As shown, the memory cell 200 includes a first pull-up (PU0) transistor, a second pull-up (PU1) transistor, a first pull-down (PD0) transistor, a second pull-down (PD1) transistor, a first write pass-gate (WPG0) transistor, a second write pass-gate (WPG1) transistor, and a read pass-gate (RPG0) transistor. In some embodiments, the PU0 transistor, PU1 transistor, WPG0 transistor, and WPG1 transistor are each implemented as a p-type transistor, and the PD0 transistor, PD1 transistor, and RPG0 transistor are each implemented as an n-type transistor. In one configuration, the n-type transistors and p-type transistors can be formed as a plurality of gate-all-around (GAA) transistors disposed across a single layer of a substrate. In another configuration, the n-type transistors and p-type transistors can be formed as a plurality of fin-based transistors (FinFETs) disposed across a single layer of a substrate. In yet another configuration, the n-type transistors and p-type transistors can be formed as a plurality of GAA transistors disposed in respective layers over a substrate, which is sometimes referred to as a complementary field-effect-transistor (CFET) structure.

The PU0 transistor and PD0 transistor operatively form a first inverter, and the PU0 transistor and PD1 transistor operatively form a second inverter, in which the first inverter and the second inverter are cross-coupled with each other. For example, the first inverter has an input (node Q), at tied gate terminals of the PU0 and PD0 transistors, connected to an output of the second inverter, at tied drain terminals of the PU1 and PD1 transistors, and an output (node QB), at tied drain terminals of the PU0 and PD0 transistors, connected to an input of the second inverter, at tied gate terminals of the PU1 and PD1 transistors. The cross-coupled inverters are coupled between power supplies (VDD and VSS), and reinforce each other to maintain one of two possible logic states with a stored data bit at one of the nodes between the inverters (node Q) and the complement of that bit at the other node between the inverters (node QB). Node Q and node QB are sometimes referred to as a first storage node and a second storage node of the memory cell 200, respectively. The WPG0 transistor is coupled between node QB (the second storage node) and a first write bit line WBL, and the WPG1 transistor is coupled between node Q (the first storage node) and a second write bit line WBLB. The WPG0 transistor and WPG1 transistor have their respective gate terminals connected to a write word line WWL. The RPG0 transistor is coupled between node QB (the second storage node) and a read bit line RBL. The RPG0 transistor has its gate terminal connected to a read word line RWL.

In some embodiments, during a standby mode, neither the write word line WWL nor the read word line RWL is asserted, and thus the WPG0 transistor and WPG1 transistor disconnect the memory cell 200 from the write bit lines WBL and WBLB, respectively, and the RPG0 transistor disconnects the memory cell 200 from the read bit line RBL. For example, the write word line WWL is pulled up to a logic high state, and the read word line RWL is pulled down to a logic low state. For a read operation, the read bit line RBL may be first pre-charged to a high logic state, and the read word line RWL is asserted (e.g., by being pulled up). The stored data bit at node QB can be transferred to the read bit line RBL, a logic state of which may be distinguished by a coupled sense amplifier (not shown). For a write operation, the logic state to be written is provided at the write bit line WBL, and the complement of that logic state is provided at the write bit line WBLB, when the write word line WWL is asserted (e.g., by being pulled down).

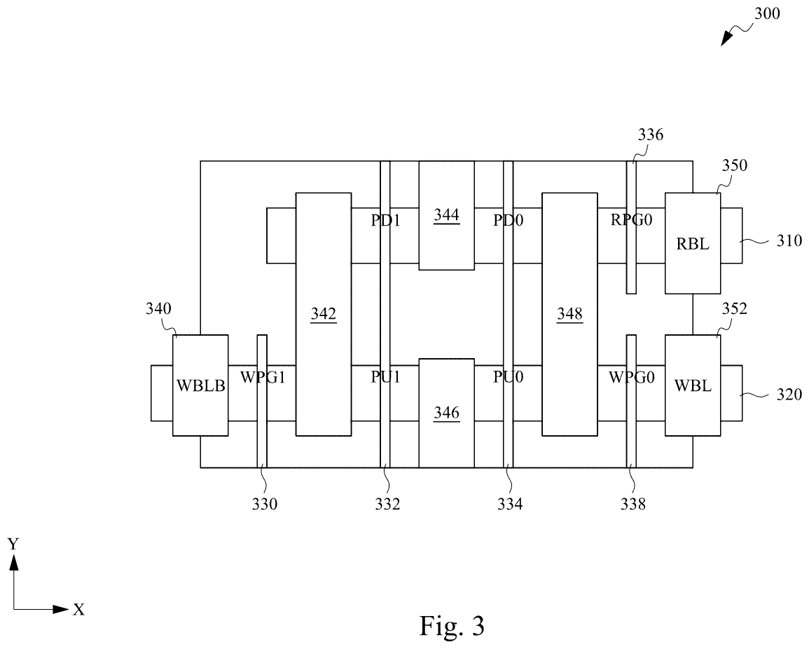

FIG. 3 illustrates an example layout 300 that can be utilized to form the memory cell 200 shown in FIG. 2, in accordance with some embodiments. For example, the layout 300 may be utilized to form each of the transistors of the memory cell 200 as a GAA transistor or a FinFET. However, it should be understood that the layout of FIG. 3 is provided merely for illustrative purposes, and is not intended to limit the scope of the present disclosure.

As shown, the layout 300 includes patterns for forming active regions 310 and 320, gate structures 330, 332, 334, 336, and 338, respectively. It should be understood that the layout 300 can include any number of other patterns to form respective active regions or gate structures, while remaining within the scope of present disclosure. The active regions 310 and 320 can each extend along a first lateral direction (e.g., the X-direction), and the gate structures 330 to 338 can each extend along a second lateral direction (e.g., the Y-direction) perpendicular to the first lateral direction. In some embodiments, the active regions 310 and 320 can each extend along the X-direction with a respective length, with the length of the active region 320 being longer than the length of the active region 310. The gate structures 330 to 338 can each traverse one or more of the active regions 310 and 320. For example, the gate structure 330 traverses only the active region 320; the gate structure 332 traverses both the active regions 310 and 320; the gate structure 334 traverses both the active regions 310 and 320; and the gate structure 336 traverses only the active region 310 while the gate structure 338, spaced from the gate structure 336 along the Y-direction but aligned with the gate structure 336 along the Y-direction, traverses only the active region 320.

In the non-limiting example where the transistors of the memory cell 200 are formed based on the GAA transistor structure, the active regions 310 and 320 can each be formed as a stack structure protruding from the frontside surface of a substrate. The stack structure includes a number of semiconductor nanostructures (e.g., nanosheets) extending along the X-direction and vertically separated from each other. Respective portions of the semiconductor nanostructures in the stack structure that are overlaid by each of the one or more gate structures 330 to 338 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., straddles) the remaining portions of the semiconductor structures can be configured as a gate terminal of the transistor.

For example, the PD1 transistor can be formed by the gate structure 332 and the active region 310, with source/drain terminals of the PD1 transistor formed in the active region 310 and on opposite sides of the gate structure 332; the PD0 transistor can be formed by the gate structure 334 and the active region 310, with source/drain terminals of the PD0 transistor formed in the active region 310 and on opposite sides of the gate structure 334; the RPG0 transistor can be formed by the gate structure 336 and the active region 310, with source/drain terminals of the RPG0 transistor formed in the active region 310 and on opposite sides of the gate structure 336; the WPG1 transistor can be formed by the gate structure 330 and the active region 320, with source/drain terminals of the WPG1 transistor formed in the active region 320 and on opposite sides of the gate structure 330; the PU1 transistor can be formed by the gate structure 332 and the active region 320, with source/drain terminals of the PU1 transistor formed in the active region 320 and on opposite sides of the gate structure 332; the PU0 transistor can be formed by the gate structure 334 and the active region 320, with source/drain terminals of the PU0 transistor formed in the active region 320 and on opposite sides of the gate structure 334; and the WPG0 transistor can be formed by the gate structure 338 and the active region 320, with source/drain terminals of the WPG0 transistor formed in the active region 320 and on opposite sides of the gate structure 338.

The layout 300 further includes patterns for forming contact structures 340, 342, 344, 346, 348, 350, and 352, respectively. The contact structures 340 to 352 can each extend along the Y-direction, and each be interposed between adjacent ones of the gate structures. Each of the contact structures 340 to 352 is in electrical and physical contact with one or more of the epitaxial structures formed in the active regions (e.g., one or more of the source/drain terminals of the transistors of the memory cell 200). Such a contact structure is sometimes referred to as an MD.

For example, MD 340 is electrically coupled to a first source/drain terminal of the WPG1 transistor; MD 342 is electrically coupled to a second source/drain terminal of the WPG1 transistor (which is also a first source/drain terminal of the PU1 transistor) and a first source/drain terminal of the PD1 transistor; MD 344 is electrically coupled to a second source/drain terminal of the PD1 transistor and a first source/drain terminal of the PD0 transistor; MD 346 is electrically coupled to a second source/drain terminal of the PU1 transistor and a first source/drain terminal of the PU0 transistor; MD 348 is electrically coupled to a second source/drain terminal of the PD0 transistor (which is also a first source/drain terminal of the RPG0 transistor) and a second source/drain terminal of the PU0 transistor (which is also a first source/drain terminal of the WPG0 transistor); MD 350 is electrically coupled to a second source/drain terminal of the RPG0 transistor; and MD 352 is electrically coupled to a second source/drain terminal of the WPG0 transistor.

With the layout 300 shown in FIG. 3, the gate structures 330 and 338 (the gate terminals of the WPG0 and WPG1 transistors, respectively) can be commonly coupled to an interconnect structure (not shown) that operatively serves as at least a part of the write word line WWL; the gate structure 336 (the gate terminal of the RPG0 transistor) can be coupled to another interconnect structure (not shown) that operatively serves as at least a part of the read word line RWL; the MD 340 can operatively serve as at least a part of the write bit line WBLB; the MD 350 can operatively serve as at least a part of the read bit line RBL; and the MD 352 can operatively serve as at least a part of the write bit line WBL.

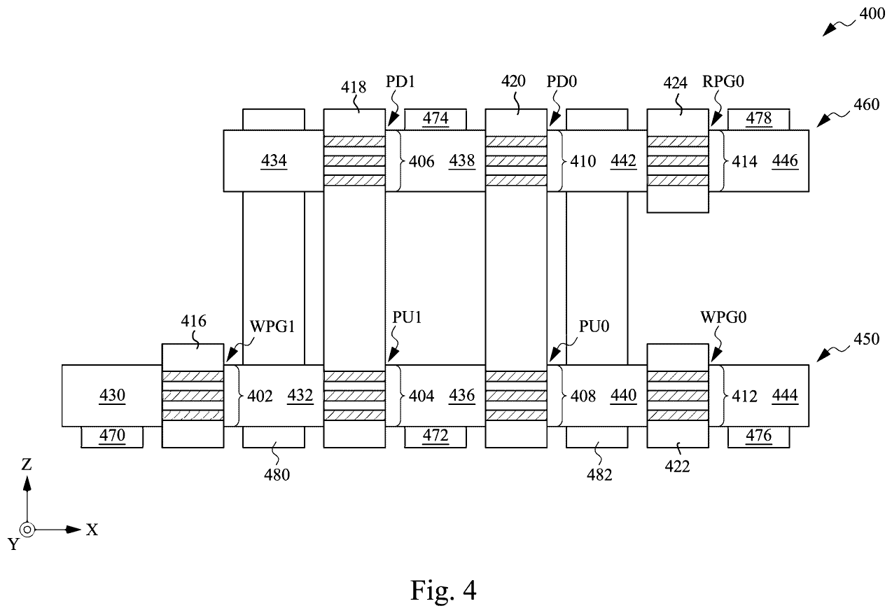

FIG. 4 illustrates a cross-sectional view of an example semiconductor structure 400 configured to implement the transistors of the memory cell 200, in accordance with some embodiments. The semiconductor structure 400 is formed based on a CFET structure, with the transistors having a first conductive type formed in a first layer and the transistors having a second conductive type formed in a second layer that is vertically spaced from the first layer. As mentioned above, the memory cell 200 can be formed in any of various other transistor structure, and thus, it should be understood that the semiconductor structure 400 shown in FIG. 4 it not intended to limit the scope of the present disclosure.

As shown in FIG. 4, the semiconductor structure 400 includes a first group of semiconductor nanostructures 402 vertically spaced from one another, a second group of semiconductor nanostructures 404 vertically spaced from one another, a third group of semiconductor nanostructures 406 vertically spaced from one another, a fourth group of semiconductor nanostructures 408 vertically spaced from one another, a fifth group of semiconductor nanostructures 410 vertically spaced from one another, a sixth group of semiconductor nanostructures 412 vertically spaced from one another, and a seventh group of semiconductor nanostructures 414 vertically spaced from one another. In some embodiments, the semiconductor nanostructures 402, 404, 408, and 412 are formed from a first active region 450 in a first layer and the semiconductor nanostructures 406, 410, and 414 are formed from a second active region 460 in a second layer above the first layer. Each of the semiconductor nanostructures 402 to 414 can be formed as a nanosheet that extends along a first lateral direction (e.g., the X-direction).

In some embodiments, the semiconductor structures 402 to 414 may each include silicon. Alternatively, the semiconductor structures 402 to 414 may each include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. Further, each of the semiconductor structures 402 to 414 may be undoped, that is, the semiconductor structures 402 to 414 being dopant-free (e.g., having an extrinsic dopant concentration from about 0 cm⁻³ to about 1×10¹⁷ cm⁻³), where no intentional doping is performed during a growth process of those semiconductor structures.

The semiconductor structure 400 further includes a first gate structure 416, a second gate structure 418, a third gate structure 420, a fourth gate structure 422, and a fifth gate structure 424. Each of the gate structures 416 to 424 can extend along a second lateral direction (e.g., the Y-direction). The gate structure 416 can wrap around each of the semiconductor nanostructures 402, the gate structure 418 can wrap around each of the semiconductor nanostructures 404 and each of the semiconductor nanostructures 406, the gate structure 420 can wrap around each of the semiconductor nanostructures 408 and each of the semiconductor nanostructures 410, the gate structure 422 can wrap around each of the semiconductor nanostructures 412, and the gate structure 424 can wrap around each of the semiconductor nanostructures 414.

In some embodiments, the gate structures 416 to 424 may each include at least one high-k dielectric layer and at least one gate electrode layer. The high-k dielectric layer may include a dielectric material such as, for example, HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or combinations thereof. The gate electrode layer may include a metal material such as, for example, Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or combinations thereof.

The semiconductor structure 400 further includes epitaxial structures 430, 432, 434, 436, 438, 440, 442, 444, and 446. The epitaxial structures 430 and 432, on the opposite sides of the gate structure 416, are electrically coupled to each of the semiconductor nanostructures 402. The epitaxial structures 432 and 436, on the opposite sides of the gate structure 418, are electrically coupled to each of the semiconductor nanostructures 404. The epitaxial structures 434 and 438, on the opposite sides of the gate structure 418, are electrically coupled to each of the semiconductor nanostructures 406. The epitaxial structures 436 and 440, on the opposite sides of the gate structure 420, are electrically coupled to each of the semiconductor nanostructures 408. The epitaxial structures 438 and 442, on the opposite sides of the gate structure 420, are electrically coupled to each of the semiconductor nanostructures 410. The epitaxial structures 440 and 444, on the opposite sides of the gate structure 422, are electrically coupled to each of the semiconductor nanostructures 412. The epitaxial structures 442 and 446, on the opposite sides of the gate structure 424, are electrically coupled to each of the semiconductor nanostructures 414. In some embodiments, the epitaxial structures 430, 432, 436, 440, and 444, formed in the first active region 450, may have p-type (e.g., with p-type impurities), and the epitaxial structures 434, 438, 442, and 446, formed in the second active region 460, may have n-type (e.g., with n-type impurities). As shown in FIG. 4, the WPG1, PU1, PU0, WPG0, PD1, PD0, and RPG0 transistors can be formed.

The semiconductor structure 400 further includes contact structures 470, 472, 474, 476, 478, 480, and 482. The contact structure 470 is in electrical contact with the epitaxial structure 430 (one of the source/drain terminals of the WPG1 transistor); the contact structure 472 is in electrical contact with the epitaxial structure 436 (one of the source/drain terminals of the PU1 transistor and one of the source/drain terminals of the PU0 transistor); the contact structure 474 is in electrical contact with the epitaxial structure 438 (one of the source/drain terminals of the PD1 transistor and one of the source/drain terminals of the PD0 transistor); the contact structure 476 is in electrical contact with the epitaxial structure 444 (one of the source/drain terminals of the WPG0 transistor); and the contact structure 478 is in electrical contact with the epitaxial structure 446 (one of the source/drain terminals of the RPG0 transistor). As such, the contact structure 470 can operatively serve as or be coupled to a part of the write bit line WBLB, the contact structure 472 can operatively serve as or be coupled to a power rail carrying VDD, the contact structure 474 can operatively serve as or be coupled to another power rail carrying VSS, the contact structure 476 can operatively serve as or be coupled to a part of the write bit line WBL, and the contact structure 478 can operatively serve as or be coupled to a part of the read bit line RBL. Further, the contact structure 480 can electrically connect the epitaxial structure 432 (one of the source/drain terminals of the PU1 transistor which is also one of the source/drain terminals of the WPG1 transistor) and the epitaxial structure 434 (one of the source/drain terminals of the PD1 transistor), and the contact structure 482 can electrically connect the epitaxial structure 440 (one of the source/drain terminals of the PU0 transistor which is also one of the source/drain terminals of the WPG0 transistor) and the epitaxial structure 442 (one of the source/drain terminals of the PD0 transistor which is also one of the source/drain terminals of the RPG0 transistor).

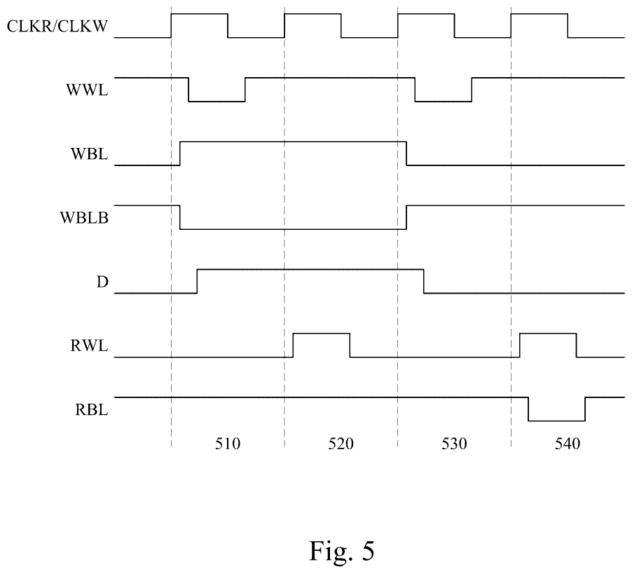

FIG. 5 illustrate waveforms of signals operating the memory cell 200 (FIG. 2) over time, respectively, in accordance with some embodiments. For example, a clock signal (hereinafter referred to as “CLKR/CLKW signal”), a signal applied on the write word line WWL (hereinafter referred to as “WWL signal”), a signal applied on the write bit line WBL (hereinafter referred to as “WBL signal”), a signal applied on the write bit line WBLB (hereinafter referred to as “WBLB signal”), a signal present on node QB (hereinafter referred to as “D signal”), a signal applied on the read word line RWL (hereinafter referred to as “RWL signal”), and a signal present on the read bit line RBL (hereinafter referred to as “RBL signal”) are each shown over four phases 510, 520, 530, and 540.

In the phase 510, the memory cell 200 is written with a data bit. For example, the WWL signal is pulled down, which activates the WPG0 and WPG1 transistors, and the RWL signal is pulled down or kept in a logic low state, which deactivates the RPG0 transistor. Accordingly, the write bit line WBL, with the WBL signal supplied with a logic high state, is coupled to node QB, the write bit line WBLB, with the WBLB signal supplied with a logic low state, is coupled to node Q, and the read bit line RBL, pre-charged to a logic high state, is decoupled from node QB. As such, a logic 1 can be written to node QB (with a logic 0 written to node Q), as illustrated by the D signal.

In the phase 520, the data bit written to the memory cell 200 during the phase 510 is read. For example, the WWL signal is pulled up or kept in a logic high state, which deactivates the WPG0 and WPG1 transistors, and the RWL signal is pulled up, which activates the RPG0 transistor. Accordingly, the write bit line WBL is decoupled from node QB, and the write bit line WBLB is decoupled from node Q. Further, with the RPG0 transistor activated, the read bit line RBL is coupled to node QB, which allows the D signal to transfer to or be present on the read bit line RBL. As such, a logic 1 written to node QB (with a logic 0 written to node Q) can be read out through the RBL signal.

In the phase 530, the memory cell 200 is written with another data bit. For example, the WWL signal is pulled down, which activates the WPG0 and WPG1 transistors, and the RWL signal is pulled down or kept in a logic low state, which deactivates the RPG0 transistor. Accordingly, the write bit line WBL, with the WBL signal supplied with a logic low state, is coupled to node QB, the write bit line WBLB, with the WBLB signal supplied with a logic high state, is coupled to node Q, and the read bit line RBL, pre-charged to or kept in a logic high state, is decoupled from node QB. As such, a logic 0 can be written to node QB (with a logic 1 written to node Q), as illustrated by the D signal.

In the phase 540, the data bit written to the memory cell 200 during the phase 530 is read. For example, the WWL signal is pulled up or kept in a logic high state, which deactivates the WPG0 and WPG1 transistors, and the RWL signal is pulled up, which activates the RPG0 transistor. Accordingly, the write bit line WBL is decoupled from node QB, and the write bit line WBLB is decoupled from node Q. Further, with the RPG0 transistor activated, the read bit line RBL is coupled to node QB, which allows the D signal to transfer to or be present on the read bit line RBL. As such, a logic 0 written to node QB (with a logic 1 written to node Q) can be read out through the RBL signal.

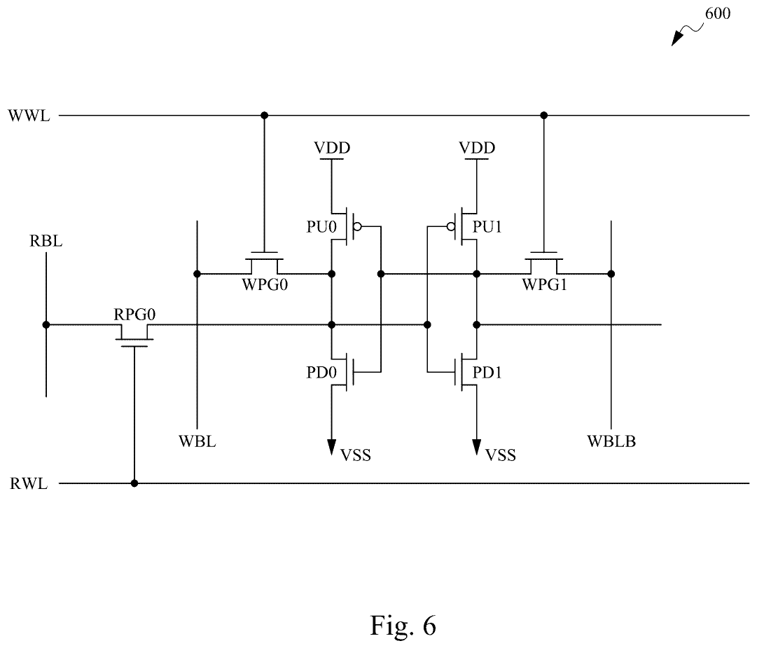

FIG. 6 illustrates an example circuit diagram 600 of another implementation of the memory cell 125 shown in FIG. 1 (hereinafter “memory cell 600”), in accordance with some embodiments. The memory cell 600 is substantially similar to the memory cell 200 (FIG. 2), except that the WPG0 and WPG1 transistors are each implemented as an n-type transistor. Accordingly, the description is not repeated.

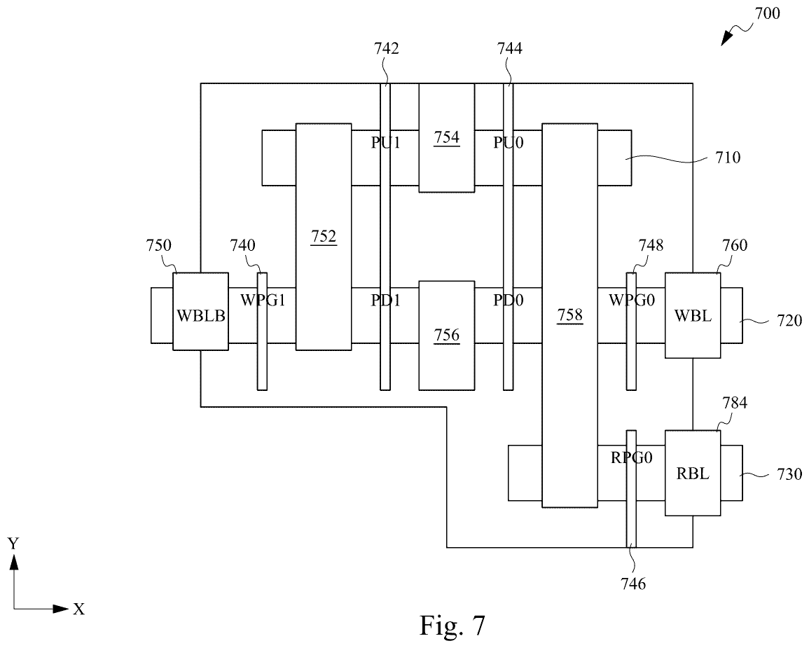

FIG. 7 illustrates an example layout 700 that can be utilized to form the memory cell 600 shown in FIG. 6, in accordance with some embodiments. For example, the layout 700 may be utilized to form each of the transistors of the memory cell 600 as a GAA transistor or a FinFET. However, it should be understood that the layout of FIG. 7 is provided merely for illustrative purposes, and is not intended to limit the scope of the present disclosure.

As shown, the layout 700 includes patterns for forming active regions 710, 720, and 730, gate structures 740, 742, 744, 746, and 748, respectively. It should be understood that the layout 700 can include any number of other patterns to form respective active regions or gate structures, while remaining within the scope of present disclosure. The active regions 710 to 730 can each extend along a first lateral direction (e.g., the X-direction), and the gate structures 740 to 748 can each extend along a second lateral direction (e.g., the Y-direction) perpendicular to the first lateral direction. In some embodiments, the active region 720 is interposed between the active regions 710 and 730. The gate structures 740 to 748 can each traverse one or more of the active regions 710 and 730. For example, the gate structure 740 traverses only the active region 720; the gate structure 742 traverses both the active regions 710 and 720; the gate structure 744 traverses both the active regions 710 and 720; and the gate structure 748 traverses only the active region 720 while the gate structure 746, spaced from the gate structure 748 along the Y-direction but aligned with the gate structure 748 along the Y-direction, traverses only the active region 730.

In the non-limiting example where the transistors of the memory cell 600 are formed based on the GAA transistor structure, the active regions 710 to 730 can each be formed as a stack structure protruding from the frontside surface of a substrate. The stack structure includes a number of semiconductor nanostructures (e.g., nanosheets) extending along the X-direction and vertically separated from each other. Respective portions of the semiconductor nanostructures in the stack structure that are overlaid by each of the one or more gate structures 740 to 748 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., straddles) the remaining portions of the semiconductor structures can be configured as a gate terminal of the transistor.

For example, the PD1 transistor can be formed by the gate structure 742 and the active region 720, with source/drain terminals of the PD1 transistor formed in the active region 720 and on opposite sides of the gate structure 742; the PD0 transistor can be formed by the gate structure 744 and the active region 720, with source/drain terminals of the PD0 transistor formed in the active region 720 and on opposite sides of the gate structure 744; the RPG0 transistor can be formed by the gate structure 746 and the active region 730, with source/drain terminals of the RPG0 transistor formed in the active region 730 and on opposite sides of the gate structure 746; the WPG1 transistor can be formed by the gate structure 740 and the active region 720, with source/drain terminals of the WPG1 transistor formed in the active region 720 and on opposite sides of the gate structure 740; the PU1 transistor can be formed by the gate structure 742 and the active region 710, with source/drain terminals of the PU1 transistor formed in the active region 710 and on opposite sides of the gate structure 742; the PU0 transistor can be formed by the gate structure 744 and the active region 710, with source/drain terminals of the PU0 transistor formed in the active region 710 and on opposite sides of the gate structure 744; and the WPG0 transistor can be formed by the gate structure 748 and the active region 720, with source/drain terminals of the WPG0 transistor formed in the active region 720 and on opposite sides of the gate structure 748

The layout 700 further includes patterns for forming contact structures 750, 752, 754, 756, 758, 760, and 762, respectively. The contact structures 750 to 762 can each extend along the Y-direction, and each be interposed between adjacent ones of the gate structures. Each of the contact structures 750 to 762 is in electrical and physical contact with one or more of the epitaxial structures formed in the active regions (e.g., one or more of the source/drain terminals of the transistors of the memory cell 600). Such a contact structure is sometimes referred to as an MD.

For example, MD 750 is electrically coupled to a first source/drain terminal of the WPG1 transistor; MD 752 is electrically coupled to a second source/drain terminal of the WPG1 transistor (which is also a first source/drain terminal of the PD1 transistor) and a first source/drain terminal of the PU1 transistor; MD 754 is electrically coupled to a second source/drain terminal of the PU1 transistor and a first source/drain terminal of the PU0 transistor; MD 756 is electrically coupled to a second source/drain terminal of the PD1 transistor and a first source/drain terminal of the PD0 transistor; MD 758 is electrically coupled to a second source/drain terminal of the PU0 transistor, a second source/drain terminal of the PD0 transistor (which is also a first source/drain terminal of the WPG0 transistor), and a first source/drain terminal of the RPG0 transistor; MD 760 is electrically coupled to a second source/drain terminal of the WPG0 transistor; and MD 362 is electrically coupled to a second source/drain terminal of the RPG0 transistor.

With the layout 700 shown in FIG. 7, the gate structures 740 and 748 (the gate terminals of the WPG0 and WPG1 transistors, respectively) can be commonly coupled to an interconnect structure (not shown) that operatively serves as at least a part of the write word line WWL; the gate structure 746 (the gate terminal of the RPG0 transistor) can be coupled to another interconnect structure (not shown) that operatively serves as at least a part of the read word line RWL; the MD 750 can operatively serve as at least a part of the write bit line WBLB; the MD 762 can operatively serve as at least a part of the read bit line RBL; and the MD 760 can operatively serve as at least a part of the write bit line WBL.

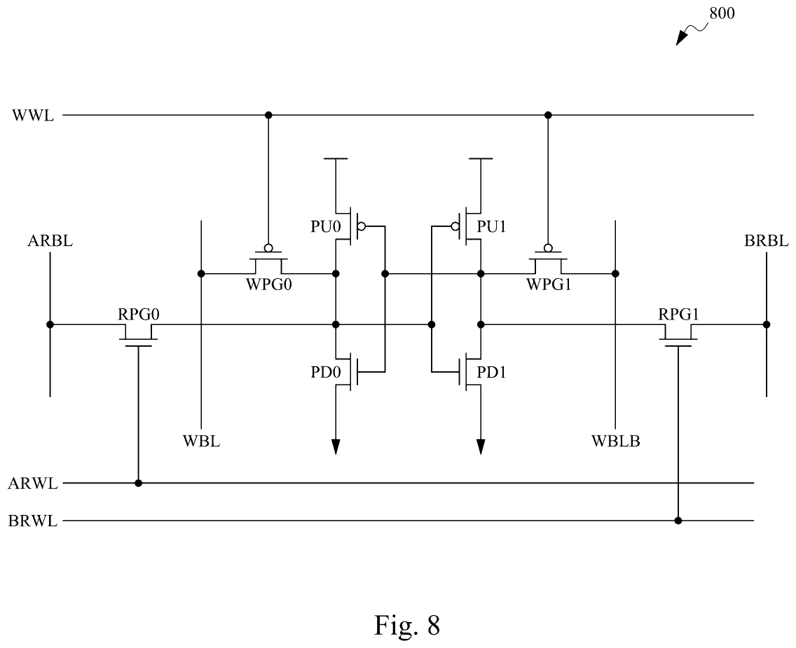

FIG. 8 illustrates an example circuit diagram 800 of yet another implementation of the memory cell 125 shown in FIG. 1 (hereinafter “memory cell 800”), in accordance with some embodiments. As disclosed herein, the memory cell 800 can sometimes be referred to as an 8T SRAM cell, with two read ports and one write port. For example, a first one of the read ports (e.g., including a first read bit line ARBL and a first read word line ARWL) and a second one of the read ports (e.g., including a second read bit line BRBL and a second read word line BRWL) may be operative in accordance with a first clock signal, and the write port (e.g., including a pair of write bit lines, WBL and WBLB, and a write word line WWL) may be operative in accordance with a second clock signal. However, it should be understood that the memory cell 800 can be implemented as any of various other multi-port SRAM cell, while remaining within the scope of the present disclosure.

As shown, the memory cell 800 includes a first pull-up (PU0) transistor, a second pull-up (PU1) transistor, a first pull-down (PD0) transistor, a second pull-down (PD1) transistor, a first write pass-gate (WPG0) transistor, a second write pass-gate (WPG1) transistor, a first read pass-gate (RPG0) transistor, and a second read pass-gate (RPG1) transistor. In some embodiments, the PU0 transistor, PU1 transistor, WPG0 transistor, and WPG1 transistor are each implemented as a p-type transistor, and the PD0 transistor, PD1 transistor, RPG0 transistor, and RPG1 transistor are each implemented as an n-type transistor. In one configuration, the n-type transistors and p-type transistors can be formed as a plurality of gate-all-around (GAA) transistors disposed across a single layer of a substrate. In another configuration, the n-type transistors and p-type transistors can be formed as a plurality of fin-based transistors (FinFETs) disposed across a single layer of a substrate. In yet another configuration, the n-type transistors and p-type transistors can be formed as a plurality of GAA transistors disposed in respective layers over a substrate, which is sometimes referred to as a complementary field-effect-transistor (CFET) structure.

The PU0 transistor and PD0 transistor operatively form a first inverter, and the PU1 transistor and PD1 transistor operatively form a second inverter, in which the first inverter and the second inverter are cross-coupled with each other. For example, the first inverter has an input (node Q), at tied gate terminals of the PU0 and PD0 transistors, connected to an output of the second inverter, at tied drain terminals of the PU1 and PD1 transistors, and an output (node QB), at tied drain terminals of the PU0 and PD0 transistors, connected to an input of the second inverter, at tied gate terminals of the PU1 and PD1 transistors. The cross-coupled inverters are coupled between power supplies (VDD and VSS), and reinforce each other to maintain one of two possible logic states with a stored data bit at one of the nodes between the inverters (node Q) and the complement of that bit at the other node between the inverters (node QB). Node Q and node QB are sometimes referred to as a first storage node and a second storage node of the memory cell 800, respectively. The WPG0 transistor is coupled between node QB (the second storage node) and a first write bit line WBL, and the WPG1 transistor is coupled between node Q (the first storage node) and a second write bit line WBLB. The WPG0 transistor and WPG1 transistor have their respective gate terminals connected to a write word line WWL. The RPG0 transistor is coupled between node QB (the second storage node) and a first read bit line ARBL, the RPG1 transistor is coupled between node Q (the first storage node) and a second read bit line BRBL. The RPG0 transistor has its gate terminal connected to a first read word line ARWL, and the RPG1 transistor has its gate terminal connected to a second read word line BRWL.

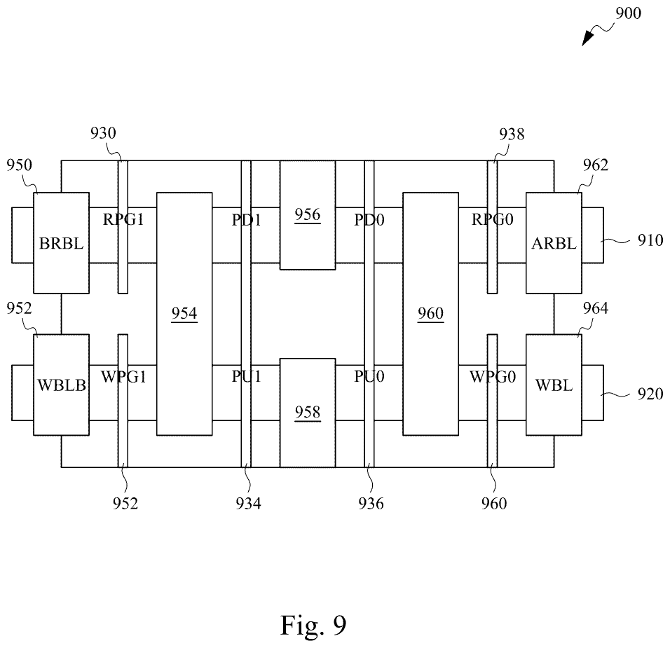

FIG. 9 illustrates an example layout 900 that can be utilized to form the memory cell 800 shown in FIG. 8, in accordance with some embodiments. For example, the layout 900 may be utilized to form each of the transistors of the memory cell 800 as a GAA transistor or a FinFET. However, it should be understood that the layout of FIG. 9 is provided merely for illustrative purposes, and is not intended to limit the scope of the present disclosure.

As shown, the layout 900 includes patterns for forming active regions 910 and 920, gate structures 930, 932, 934, 936, 938, and 940, respectively. It should be understood that the layout 900 can include any number of other patterns to form respective active regions or gate structures, while remaining within the scope of present disclosure. The active regions 910 and 920 can each extend along a first lateral direction (e.g., the X-direction), and the gate structures 930 to 940 can each extend along a second lateral direction (e.g., the Y-direction) perpendicular to the first lateral direction. In some embodiments, the active regions 910 and 920 can each extend along the X-direction with a respective length, with the length of the active region 920 being equal to the length of the active region 910. The gate structures 930 to 940 can each traverse one or more of the active regions 910 and 920. For example, the gate structure 930 traverses only the active region 910; the gate structure 932 traverses only the active region 920; the gate structure 934 traverses both the active regions 910 and 920; the gate structure 936 traverses both the active regions 910 and 920; the gate structure 938 traverses only the active region 910; and the gate structure 940 traverses only the active region 920. Further, the gate structure 930 is spaced from the gate structure 932 along the Y-direction but aligned with the gate structure 932 along the Y-direction, and the gate structure 938 is spaced from the gate structure 940 along the Y-direction but aligned with the gate structure 940 along the Y-direction.

In the non-limiting example where the transistors of the memory cell 800 are formed based on the GAA transistor structure, the active regions 910 and 920 can each be formed as a stack structure protruding from the frontside surface of a substrate. The stack structure includes a number of semiconductor nanostructures (e.g., nanosheets) extending along the X-direction and vertically separated from each other. Respective portions of the semiconductor nanostructures in the stack structure that are overlaid by each of the one or more gate structures 930 to 940 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., straddles) the remaining portions of the semiconductor structures can be configured as a gate terminal of the transistor.

For example, the PD1 transistor can be formed by the gate structure 934 and the active region 910, with source/drain terminals of the PD1 transistor formed in the active region 910 and on opposite sides of the gate structure 934; the PD0 transistor can be formed by the gate structure 936 and the active region 910, with source/drain terminals of the PD0 transistor formed in the active region 910 and on opposite sides of the gate structure 936; the RPG0 transistor can be formed by the gate structure 938 and the active region 910, with source/drain terminals of the RPG0 transistor formed in the active region 910 and on opposite sides of the gate structure 938; the RPG1 transistor can be formed by the gate structure 930 and the active region 910, with source/drain terminals of the RPG1 transistor formed in the active region 910 and on opposite sides of the gate structure 930; the WPG1 transistor can be formed by the gate structure 932 and the active region 920, with source/drain terminals of the WPG1 transistor formed in the active region 920 and on opposite sides of the gate structure 932; the PU1 transistor can be formed by the gate structure 934 and the active region 920, with source/drain terminals of the PU1 transistor formed in the active region 920 and on opposite sides of the gate structure 934; the PU0 transistor can be formed by the gate structure 936 and the active region 920, with source/drain terminals of the PU0 transistor formed in the active region 920 and on opposite sides of the gate structure 936; and the WPG0 transistor can be formed by the gate structure 940 and the active region 920, with source/drain terminals of the WPG0 transistor formed in the active region 920 and on opposite sides of the gate structure 940.

The layout 900 further includes patterns for forming contact structures 950, 952, 954, 956, 958, 960, 962, and 964, respectively. The contact structures 950 to 964 can each extend along the Y-direction, and each be interposed between adjacent ones of the gate structures. Each of the contact structures 950 to 964 is in electrical and physical contact with one or more of the epitaxial structures formed in the active regions (e.g., one or more of the source/drain terminals of the transistors of the memory cell 800). Such a contact structure is sometimes referred to as an MD.

For example, MD 950 is electrically coupled to a first source/drain terminal of the RPG1 transistor; MD 952 is electrically coupled to a first source/drain terminal of the WPG1 transistor; MD 954 is electrically coupled to a second source/drain terminal of the RPG1 transistor (which is also a first source/drain terminal of the PD1 transistor) and a second source/drain terminal of the WPG1 transistor (which is also a first source/drain terminal of the PU1 transistor); MD 956 is electrically coupled to a second source/drain terminal of the PD1 transistor and a first source/drain terminal of the PD0 transistor; MD 958 is electrically coupled to a second source/drain terminal of the PU1 transistor and a first source/drain terminal of the PU0 transistor; MD 960 is electrically coupled to a second source/drain terminal of the PD0 transistor (which is also a first source/drain terminal of the RPG0 transistor) and a second source/drain terminal of the PU0 transistor (which is also a first source/drain terminal of the WPG0 transistor); MD 962 is electrically coupled to a second source/drain terminal of the RPG0 transistor; and MD 964 is electrically coupled to a second source/drain terminal of the WPG0 transistor.

With the layout 900 shown in FIG. 9, the gate structures 932 and 940 (the gate terminals of the WPG0 and WPG1 transistors, respectively) can be commonly coupled to an interconnect structure (not shown) that operatively serves as at least a part of the write word line WWL; the gate structure 938 (the gate terminal of the RPG0 transistor) can be coupled to another interconnect structure (not shown) that operatively serves as at least a part of the read word line ARWL; the gate structure 930 (the gate terminal of the RPG1 transistor) can be coupled to yet another interconnect structure (not shown) that operatively serves as at least a part of the read word line BRWL; the MD 952 can operatively serve as at least a part of the write bit line WBLB; the MD 950 can operatively serve as at least a part of the read bit line BRBL; the MD 962 can operatively serve as at least a part of the read bit line ARBL; and the MD 964 can operatively serve as at least a part of the write bit line WBL.

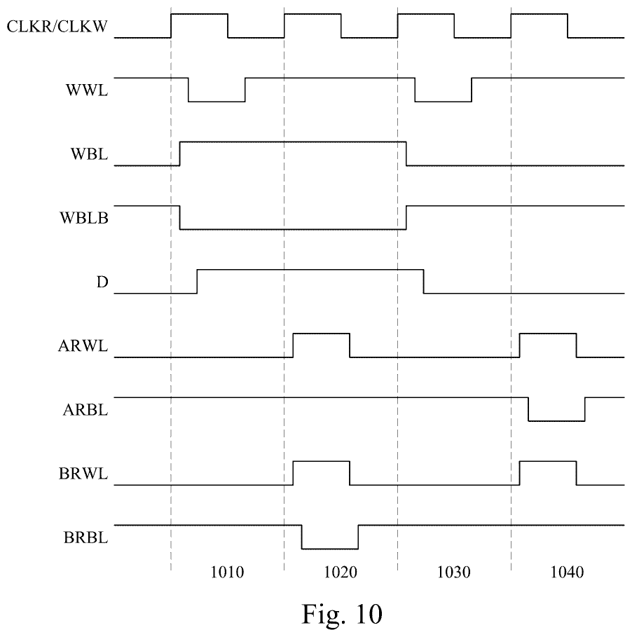

FIG. 10 illustrate waveforms of signals operating the memory cell 800 (FIG. 8) over time, respectively, in accordance with some embodiments. For example, a clock signal (hereinafter referred to as “CLKR/CLKW signal”), a signal applied on the write word line WWL (hereinafter referred to as “WWL signal”), a signal applied on the write bit line WBL (hereinafter referred to as “WBL signal”), a signal applied on the write bit line WBLB (hereinafter referred to as “WBLB signal”), a signal present on node QB (hereinafter referred to as “D signal”), a signal applied on the read word line ARWL (hereinafter referred to as “ARWL signal”), a signal applied on the read word line BRWL (hereinafter referred to as “BRWL signal”), a signal present on the read bit line ARBL (hereinafter referred to as “ARBL signal”), and a signal present on the read bit line BRBL (hereinafter referred to as “BRBL signal”) are each shown over four phases 1010, 1020, 1030, and 1040.

In the phase 1010, the memory cell 800 is written with a data bit. For example, the WWL signal is pulled down, which activates the WPG0 and WPG1 transistors, and the ARWL signal and BRWL signal are both pulled down or kept in a logic low state, which deactivates the RPG0 transistor and RPG1 transistor, respectively. Accordingly, the write bit line WBL, with the WBL signal supplied with a logic high state, is coupled to node QB, the write bit line WBLB, with the WBLB signal supplied with a logic low state, is coupled to node Q, and the read bit lines ARBL and BRBL, each pre-charged to a logic high state, are decoupled from node QB and from node Q, respectively. As such, a logic 1 can be written to node QB (with a logic 0 written to node Q), as illustrated by the D signal.

In the phase 1020, the data bit written to the memory cell 800 during the phase 1010 is read. For example, the WWL signal is pulled up or kept in a logic high state, which deactivates the WPG0 and WPG1 transistors, and the ARWL signal and BRWL signal are both pulled up, which activates the RPG0 transistor and RPG1 transistor, respectively. Accordingly, the write bit line WBL is decoupled from node QB, and the write bit line WBLB is decoupled from node Q. Further, with the RPG0 transistor activated, the read bit line ARBL is coupled to node QB, which allows the D signal to transfer to or be present on the read bit line ARBL. Concurrently or subsequently, with the RPG1 transistor activated, the read bit line BRBL is coupled to node Q, which allows a complement of the D signal to transfer to or be present on the read bit line BRBL. As such, a logic 1 written to node QB (with a logic 0 written to node Q) can be read out through the ARBL signal or the BRBL signal.

In the phase 1030, the memory cell 800 is written with another data bit. For example, the WWL signal is pulled down, which activates the WPG0 and WPG1 transistors, and the ARWL signal and BRWL signal are both pulled down or kept in a logic low state, which deactivates the RPG0 transistor and RPG1 transistor, respectively. Accordingly, the write bit line WBL, with the WBL signal supplied with a logic low state, is coupled to node QB, the write bit line WBLB, with the WBLB signal supplied with a logic high state, is coupled to node Q, and the read bit line RBL, pre-charged to or kept in a logic high state, is decoupled from node QB. As such, a logic 0 can be written to node QB (with a logic 1 written to node Q), as illustrated by the D signal.

In the phase 1040, the data bit written to the memory cell 800 during the phase 1030 is read. For example, the WWL signal is pulled up or kept in a logic high state, which deactivates the WPG0 and WPG1 transistors, and the ARWL signal and BRWL signal are both pulled up, which activates the RPG0 transistor and RPG1 transistor, respectively. Accordingly, the write bit line WBL is decoupled from node QB, and the write bit line WBLB is decoupled from node Q. Further, with the RPG0 transistor activated, the read bit line ARBL is coupled to node QB, which allows the D signal to transfer to or be present on the read bit line ARBL. Concurrently or subsequently, with the RPG1 transistor activated, the read bit line BRBL is coupled to node Q, which allows a complement of the D signal to transfer to or be present on the read bit line BRBL. As such, a logic 0 written to node QB (with a logic 1 written to node Q) can be read out through the ARBL signal or the BRBL signal.

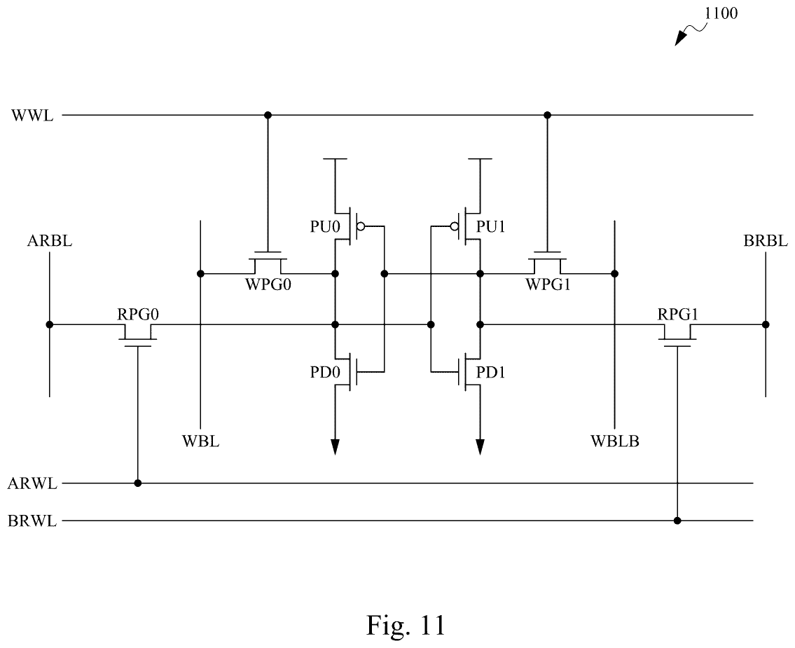

FIG. 11 illustrates an example circuit diagram 1100 of yet another implementation of the memory cell 125 shown in FIG. 1 (hereinafter “memory cell 1100”), in accordance with some embodiments. The memory cell 1100 is substantially similar to the memory cell 8200 (FIG. 8), except that the WPG0 and WPG1 transistors are each implemented as an n-type transistor. Accordingly, the description is not repeated.

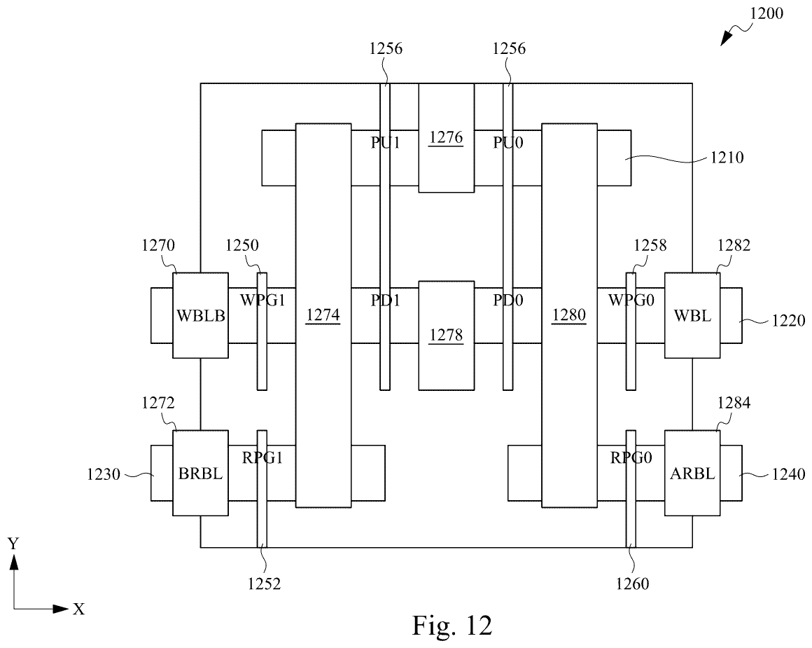

FIG. 12 illustrates an example layout 1200 that can be utilized to form the memory cell 1100 shown in FIG. 11, in accordance with some embodiments. For example, the layout 1200 may be utilized to form each of the transistors of the memory cell 1100 as a GAA transistor or a FinFET. However, it should be understood that the layout of FIG. 12 is provided merely for illustrative purposes, and is not intended to limit the scope of the present disclosure.

As shown, the layout 1200 includes patterns for forming active regions 1210, 1220, 1230, and 1240, gate structures 1250, 1252, 1254, 1256, 1258, and 1260, respectively. It should be understood that the layout 1200 can include any number of other patterns to form respective active regions or gate structures, while remaining within the scope of present disclosure. The active regions 1210 to 1240 can each extend along a first lateral direction (e.g., the X-direction), and the gate structures 1250 to 1260 can each extend along a second lateral direction (e.g., the Y-direction) perpendicular to the first lateral direction. The gate structures 1250 to 1260 can each traverse one or more of the active regions 1210 and 1240. For example, the gate structure 1250 traverses only the active region 1220; the gate structure 1252 traverses only the active region 1230; the gate structure 1254 traverses both the active regions 1210 and 1220; the gate structure 1256 traverses both the active regions 1210 and 1220; the gate structure 1258 traverses only the active region 1220; and the gate structure 1260 traverses only the active region 1220. Further, the gate structure 1250 is spaced from the gate structure 1252 along the Y-direction but aligned with the gate structure 1252 along the Y-direction, and the gate structure 1258 is spaced from the gate structure 1260 along the Y-direction but aligned with the gate structure 1260 along the Y-direction.

In the non-limiting example where the transistors of the memory cell 1100 are formed based on the GAA transistor structure, the active regions 1210 to 1240 can each be formed as a stack structure protruding from the frontside surface of a substrate. The stack structure includes a number of semiconductor nanostructures (e.g., nanosheets) extending along the X-direction and vertically separated from each other. Respective portions of the semiconductor nanostructures in the stack structure that are overlaid by each of the one or more gate structures 1252 to 1260 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., straddles) the remaining portions of the semiconductor structures can be configured as a gate terminal of the transistor.

For example, the PD1 transistor can be formed by the gate structure 1254 and the active region 1220, with source/drain terminals of the PD1 transistor formed in the active region 1220 and on opposite sides of the gate structure 1254; the PD0 transistor can be formed by the gate structure 1256 and the active region 1220, with source/drain terminals of the PD0 transistor formed in the active region 1220 and on opposite sides of the gate structure 1256; the RPG0 transistor can be formed by the gate structure 1260 and the active region 1240, with source/drain terminals of the RPG0 transistor formed in the active region 1240 and on opposite sides of the gate structure 1260; the RPG1 transistor can be formed by the gate structure 1252 and the active region 1230, with source/drain terminals of the RPG1 transistor formed in the active region 1230 and on opposite sides of the gate structure 1252; the WPG1 transistor can be formed by the gate structure 1250 and the active region 1220, with source/drain terminals of the WPG1 transistor formed in the active region 1220 and on opposite sides of the gate structure 1250; the PU1 transistor can be formed by the gate structure 1254 and the active region 1210, with source/drain terminals of the PU1 transistor formed in the active region 1210 and on opposite sides of the gate structure 1254; the PU0 transistor can be formed by the gate structure 1256 and the active region 1210, with source/drain terminals of the PU0 transistor formed in the active region 1210 and on opposite sides of the gate structure 1256; and the WPG0 transistor can be formed by the gate structure 1258 and the active region 1220, with source/drain terminals of the WPG0 transistor formed in the active region 1220 and on opposite sides of the gate structure 1258.

The layout 1200 further includes patterns for forming contact structures 1270, 1272, 1274, 1276, 1278, 1280, 1282, and 1284, respectively. The contact structures 1270 to 1284 can each extend along the Y-direction, and each be interposed between adjacent ones of the gate structures. Each of the contact structures 1270 to 1284 is in electrical and physical contact with one or more of the epitaxial structures formed in the active regions (e.g., one or more of the source/drain terminals of the transistors of the memory cell 1100). Such a contact structure is sometimes referred to as an MD.

With the layout 1200 shown in FIG. 12, the gate structures 1250 and 1258 (the gate terminals of the WPG0 and WPG1 transistors, respectively) can be commonly coupled to an interconnect structure (not shown) that operatively serves as at least a part of the write word line WWL; the gate structure 1260 (the gate terminal of the RPG0 transistor) can be coupled to another interconnect structure (not shown) that operatively serves as at least a part of the read word line ARWL; the gate structure 1252 (the gate terminal of the RPG1 transistor) can be coupled to yet another interconnect structure (not shown) that operatively serves as at least a part of the read word line BRWL; the MD 1270 can operatively serve as at least a part of the write bit line WBLB; the MD 1272 can operatively serve as at least a part of the read bit line BRBL; the MD 1284 can operatively serve as at least a part of the read bit line ARBL; and the MD 1282 can operatively serve as at least a part of the write bit line WBL.

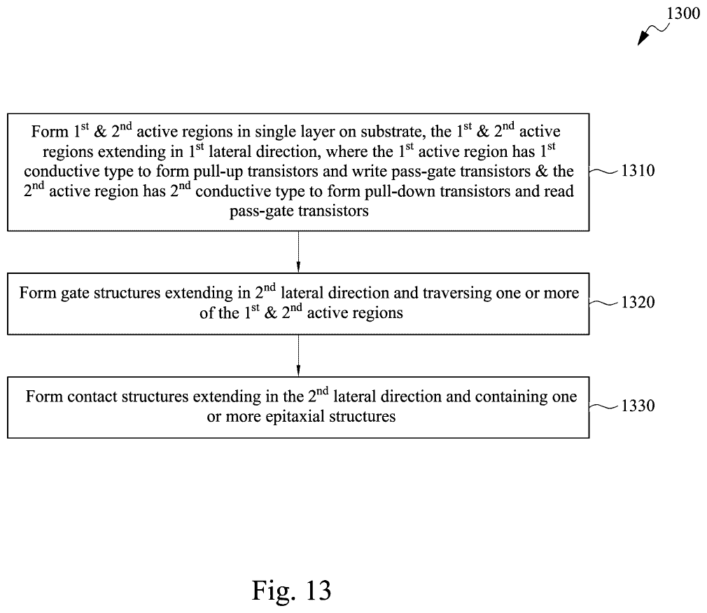

FIG. 13 illustrates a flow chart of an example method 1300 for forming a memory device (e.g., a memory cell), in accordance with various embodiments of the present disclosure. For example, operation of the method 1300 can be configured for fabricating the transistors of a memory cell (e.g., 200 of FIG. 2, 600 of FIG. 6, 800 of FIG. 8, 1100 of FIG. 11) in the structure of GAA transistors or FinFETs. Accordingly, the following discussion of the method 1300 may sometimes refer to the above figures. It should be noted that the method 1300 as shown in FIG. 13 is merely an example, and is not intended to limit the present disclosure. Thus, it is understood that the order of the operations of the method 1300 of FIG. 13 can be changed, for example, additional operations may be provided before, during, and after the method 1300, and that some operations may only be described briefly herein.

The method 1300 starts with operation 1310 of forming a number of active regions in a single layer (or level) over a semiconductor substrate, each of the active regions extending along a first lateral direction. Using the layout 300 (FIG. 3) configured for forming the memory cell 200 (FIG. 2) as a representative example, the active regions 310 and 320, extending along the X-direction, can be formed over the semiconductor substrate. The active regions 310 and 320 can be formed as a first stack and a second stack, respectively. In some embodiments, the first and second stacks may be formed on the semiconductor substrate, which are horizontally aligned with but spaced from each other. Alternatively stated, the first and second stacks are formed in a single layer (or level) over the substrate. Each of the first and second stacks includes first semiconductor layers (e.g., SiGe) and second semiconductor layers (e.g., Si) alternately staked on top of one another. The first semiconductor layers may later be replaced as one or more gate structures and the second semiconductor layers may be configured as channels of one or more transistors.

In some embodiments, a blanket stack of first semiconductor layers and second semiconductor layers is epitaxially grown on the semiconductor substrate. Each of the first semiconductor layers of a first composition is interposed between a pair of the second semiconductor layers of a second composition. The first and second composition can be different. In an embodiment, the second semiconductor layers consist of silicon germanium and the first semiconductor layers consist of silicon. However, other embodiments are possible including those that provide for a first composition and a second composition having different oxidation rates and/or etch selectivity. By way of example, epitaxial growth of the layers of the stack may be performed by a molecular beam epitaxy (MBE) process, a metalorganic chemical vapor deposition (MOCVD) process, and/or other suitable epitaxial growth processes. Following the formation of the blanket stack, the active regions can be formed by patterning the blanket stack of first and second semiconductor layers based on the corresponding patterns (e.g., 310-320 of FIG. 3, 710-730 of FIG. 7, 910-920 of FIG. 9, 1210-1240 of FIG. 12) illustrated in the layout.

The method 1300 continues to operation 1320 of forming a number of gate structures extending along a second lateral direction. Continuing with example of the layout 300 (FIG. 3), the gate structures 330 to 338, extending along the Y-direction, can be formed to traverse one or more of the active regions 310-320. In an example, the gate structures 330 to 338 can each be formed as a dummy gate structure which is subsequently removed. Following the formation of the dummy gate structures (e.g., 330 to 338) that each overlay a corresponding portion of each of the active regions 310-320, non-overlaid portions of each of each of the active regions 310-320 are removed to expose sidewalls of the second semiconductor layers that remain overlaid by the dummy gate structures. Next, epitaxial structures, which serve as source/drain terminals of respective transistors, can be grown. Next, the dummy gate structures can be replaced with metal gate structures, respectively.

To form one of the disclosed memory cells, e.g., 200 of FIG. 2, the layout 300 (FIG. 3) can be utilized to define the footprints of the active regions and gate structures. For example, after forming the active region 310 and active region 320 that extends further than the active region 310 in the X-direction, five gate structures, 330, 332, 334, 336, and 338, are formed. The gate structures 330 to 338, each extending in the Y-direction, are formed in the arrangement as shown in FIG. 3. Further, the gate structure 330 is formed to traverse only the active region 320 for forming the WPG1 transistor; the gate structure 332 is formed to traverse both the active regions 310 and 320 for forming the PD1 and PU1 transistors; the gate structure 334 is formed to traverse both the active regions 310 and 320 for forming the PD0 and PU0 transistors; the gate structure 336 is formed to traverse only the active region 310 for forming the RPG0 transistor; and the gate structure 338 is formed to traverse only the active region 320 for forming the WPG0 transistor. The gate structures 336 and 338 are aligned with each other along the Y-direction but spaced from each other along the Y-direction.

As another non-limiting example, when forming the memory cell 800 of FIG. 8, the layout 900 (FIG. 9) can be utilized. For example, after forming the active region 910 and active region 920 that have an approximately identical length in the X-direction, six gate structures, 930, 932, 934, 936, 938, and 940, are formed. The gate structures 930 to 940, each extending in the Y-direction, are formed in the arrangement as shown in FIG. 9. Further, the gate structure 930 is formed to traverse only the active region 910 for forming the RPG1 transistor; the gate structure 932 is formed to traverse only the active region 920 for forming the WPG1 transistor; the gate structure 934 is formed to traverse both the active regions 910 and 920 for forming the PD1 and PU1 transistors; the gate structure 936 is formed to traverse both the active regions 910 and 920 for forming the PD0 and PU0 transistors; the gate structure 938 is formed to traverse only the active region 910 for forming the RPG0 transistor; and the gate structure 940 is formed to traverse only the active region 920 for forming the WPG0 transistor. The gate structures 930 and 932 are aligned with each other along the Y-direction but spaced from each other along the Y-direction, and the gate structures 938 and 940 are aligned with each other along the Y-direction but spaced from each other along the Y-direction.

The method 1300 continues to operation 1330 of forming a number of contact structures extending along the second lateral direction. Continuing with example of the layout 300 (FIG. 3), the contact structures 340 to 352, extending along the Y-direction, can be formed over one or more of the epitaxial structures formed along the active regions 310-320. In an example, the contact structures 340 to 352 can each be formed as a metal structure to be in electrical and physical contact with one or more corresponding epitaxial structures. Further, each of the contact structures 340 to 352 can be configured to electrically connect respective source/drain terminals of two transistors or to electrically couple the source/drain terminal of a transistor to an access line, e.g., a read bit line RBL, a write bit line WBL, etc., in accordance with some embodiments of the present disclosure.

To form the memory cell 200 of FIG. 2, the layout 300 (FIG. 3) can be utilized to define the footprints of the contact structures 340 to 352. For example, prior to replacing the dummy gate structures with the metal gate structures, an inter-layer dielectric (ILD) layer is formed over at least the epitaxial structures. The ILD layer includes a dielectric material such as, for example, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

After forming the metal gate structures with the epitaxial structures (source/drain terminals of the transistors) overlaid by the ILD layer, the contact structure 340 is formed to contact one of the source/drain terminals of the WPG1 transistor functioning as a part of the write bit line WBLB; the contact structure 342 is formed to connect respective source/drain terminals of the WPG1 transistor, PD1 transistor, and PU1 transistor; the contact structure 344 is formed to connect respective source/drain terminals of the PD0 transistor and PD1 transistor to VSS; the contact structure 346 is formed to connect respective source/drain terminals of the PU0 transistor and PU1 transistor to VDD; the contact structure 348 is formed to connect respective source/drain terminals of the WPG0 transistor, RPG0 transistor, PD0 transistor, and PU0 transistor; the contact structure 350 is formed to contact one of the source/drain terminals of the RPG0 transistor functioning as a part of the read bit line RBL; and the contact structure 352 is formed to contact one of the source/drain terminals of the WPG0 transistor functioning as a part of the write bit line WBL.

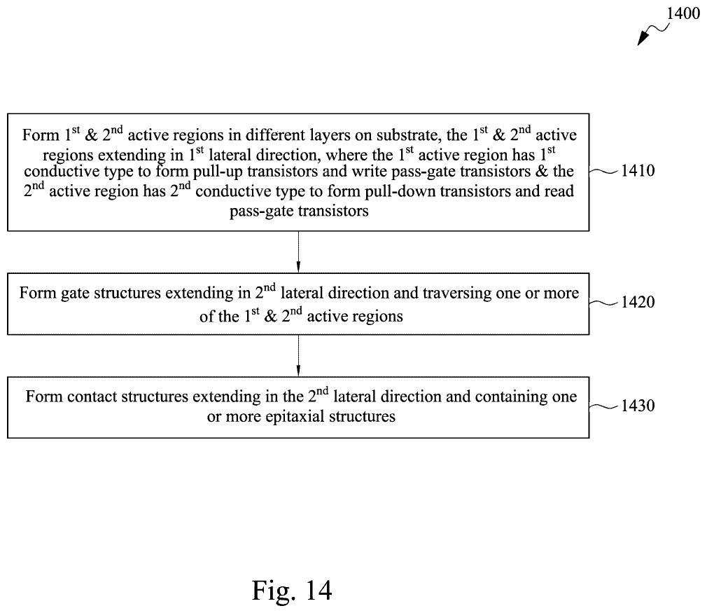

FIG. 14 illustrates a flow chart of an example method 1400 for forming a memory device (e.g., a memory cell), in accordance with various embodiments of the present disclosure. For example, operation of the method 1400 can be configured for fabricating the transistors of a memory cell (e.g., 200 of FIG. 2, 600 of FIG. 6, 800 of FIG. 8, 1100 of FIG. 11) in the structure of CFETs. Accordingly, the following discussion of the method 1400 may sometimes refer to the above figures. It should be noted that the method 1400 as shown in FIG. 14 is merely an example, and is not intended to limit the present disclosure. Thus, it is understood that the order of the operations of the method 1400 of FIG. 14 can be changed, for example, additional operations may be provided before, during, and after the method 1400, and that some operations may only be described briefly herein.

The method 1400 starts with operation 1410 of forming a first active region in a first layer (or level) over a semiconductor substrate and forming a second active region in a second layer (or level) above the first layer, each of the first and second active regions extending along a first lateral direction. Using the semiconductor structure 400 (FIG. 4) as a representative example, the first active region 450 including the later formed semiconductor structures 402, 404, 408, and 412 is first formed over the semiconductor substrate, and next, the second active region 460 including the later formed semiconductor structures 406, 410, and 414 is formed. Each of the first and second active regions, 450 and 460, can extend along the X-direction. In some embodiments, the first active region 450 and the second active region 460 may be vertically aligned (or overlapped) with each other.

The first active region 450 and second active region 460 can be formed as a first stack and a second stack, respectively. In some embodiments, the first stack may be formed on the semiconductor substrate at a first level, and the second stack may be formed at a second level above the first level. The first stack and the second stack can be vertically aligned with each other. Each of the first and second stacks includes first semiconductor layers (e.g., SiGe) and second semiconductor layers (e.g., Si) alternately staked on top of one another. The first semiconductor layers may later be replaced as one or more gate structures and the second semiconductor layers may be configured as channels of one or more transistors.

In some embodiments, a blanket stack of first semiconductor layers and second semiconductor layers is epitaxially grown on the semiconductor substrate. Further, the blanket stack can include a first group of first and second semiconductor layers, and a second group of first and second semiconductor layers, in which the first group and the second group are vertically spaced apart from each other with at least one dielectric layer. The first group can be configured to form the first active region 450, and the second group can be configured to form the second active region 460. Each of the first semiconductor layers of a first composition is interposed between a pair of the second semiconductor layers of a second composition. The first and second composition can be different. In an embodiment, the second semiconductor layers consist of silicon germanium and the first semiconductor layers consist of silicon. However, other embodiments are possible including those that provide for a first composition and a second composition having different oxidation rates and/or etch selectivity. By way of example, epitaxial growth of the layers of the stack may be performed by a molecular beam epitaxy (MBE) process, a metalorganic chemical vapor deposition (MOCVD) process, and/or other suitable epitaxial growth processes. Following the formation of the blanket stack, the first and second active regions, 450 and 460, can be formed by patterning the blanket stack of first and second semiconductor layers based on a corresponding pattern specified in a layout. For example, one single pattern can be utilized to define both of the first and second active regions, 450 and 460.

The method 1400 continues to operation 1420 of forming a number of gate structures extending along a second lateral direction. Continuing with example of the semiconductor structure 400 (FIG. 4), the gate structures 416 to 422, extending along the Y-direction, can be formed to traverse one or more of the first and second active regions, 450 and 460. In an example, the gate structures 416 to 422 can each be formed as a dummy gate structure which is subsequently removed. Following the formation of the dummy gate structures (e.g., 416 to 422) that each overlay a corresponding portion of each of the active regions 450 and 460, non-overlaid portions of each of each of the active regions 450 and 460 are removed to expose sidewalls of the second semiconductor layers that remain overlaid by the dummy gate structures. Next, epitaxial structures, which serve as source/drain terminals of respective transistors, can be grown. Next, the dummy gate structures can be replaced with metal gate structures, respectively.

For example, after forming the first active region 450 and second active region 460 that both extend in the X-direction, five gate structures, 416, 418, 420, 422, and 424, are formed. The gate structures 416 to 422, each extending in the Y-direction, are formed in the arrangement as shown in FIG. 4. Further, the gate structure 416 is formed to traverse only the active region 450 for forming the WPG1 transistor; the gate structure 418 is formed to traverse both the active regions 450 and 460 for forming the PD1 and PU1 transistors; the gate structure 420 is formed to traverse both the active regions 450 and 460 for forming the PD0 and PU0 transistors; the gate structure 422 is formed to traverse only the active region 450 for forming the WPG0 transistor; and the gate structure 424 is formed to traverse only the active region 460 for forming the RPG0 transistor. The gate structures 422 and 424 are aligned with each other along the Z-direction but spaced from each other along the Z-direction.

The method 1400 continues to operation 1430 of forming a number of contact structures extending along the second lateral direction. Continuing with example of the semiconductor structure 400 (FIG. 4), the contact structures 470 to 482, extending along the Y-direction, can be formed to contact one or more of the epitaxial structures. In an example, the contact structures 470 to 482 can each be formed as a metal structure to be in electrical and physical contact with one or more corresponding epitaxial structures. Further, each of the contact structures 470 to 482 can be configured to electrically connect respective source/drain terminals of two transistors or to electrically couple the source/drain terminal of a transistor to an access line, e.g., a read bit line RBL, a write bit line WBL, etc., in accordance with some embodiments of the present disclosure.

After forming the metal gate structures, the contact structure 470 is formed to contact one of the source/drain terminals of the WPG1 transistor functioning as a part of the write bit line WBLB; the contact structure 480 is formed to connect respective source/drain terminals of the WPG1 transistor, PD1 transistor, and PU1 transistor; the contact structure 474 is formed to connect respective source/drain terminals of the PD0 transistor and PD1 transistor to VSS; the contact structure 472 is formed to connect respective source/drain terminals of the PU0 transistor and PU1 transistor to VDD; the contact structure 482 is formed to connect respective source/drain terminals of the WPG0 transistor, RPG0 transistor, PD0 transistor, and PU0 transistor; the contact structure 478 is formed to contact one of the source/drain terminals of the RPG0 transistor functioning as a part of the read bit line RBL; and the contact structure 476 is formed to contact one of the source/drain terminals of the WPG0 transistor functioning as a part of the write bit line WBL.

In one aspect of the present disclosure, a memory device is disclosed. The memory device includes a storage element formed of a first inverter and a second inverter cross-coupled to each other; a first transistor having a first conductive type, and connected between a first bit line and a first storage node of the storage element; a second transistor having the first conductive type, and connected between a second bit line and a second storage node of the storage element; and a third transistor having a second conductive type opposite to the first conductive type, and connected between the first storage node and a third bit line.

In another aspect of the present disclosure, a memory device is disclosed. The memory device includes a memory cell consisting of a first transistor, a second transistor, a third transistor, a fourth transistor, a fifth transistor, a sixth transistor, and a seventh transistor, the memory cell configured to be read through a first bit line and a first word line, and programmed through a second bit line, a third bit line, and a second word line. The first to fourth transistors operatively form a pair of cross-coupled inverters to store a data bit with a first storage node and a second storage node. The fifth transistor and sixth transistor are commonly gated by the second word line and respectively connected to the second bit line and the third bit line. The seventh transistor is gated by the first word line and connected to the first bit line. The fifth transistor and the sixth transistor are configured in p-type, and the seventh transistor is configured in n-type.

In yet another aspect of the present disclosure, a method for forming memory devices is disclosed. The method includes forming a first active region extending along a first lateral direction with a first length, the first active region having a first conductive type. The method includes forming a second active region extending along the first lateral direction with a second length and spaced from the first active region along a second lateral direction perpendicular to the first lateral direction, the second active region having a second conductive type, the second length longer than the first length. The method includes forming a first gate structure, a second gate structure, a third gate structure, a fourth gate structure, and a fifth gate structure, each of which extends along the second lateral direction, the first gate structure traversing the second active region, the second gate structure traversing both the first and second active regions, the third second gate structure traversing both the first and second active regions, the fourth gate structure traversing the second active region, the fifth gate structure traversing the first active region. The first active region, the second active region, and the first to fifth gate structures are configured to collectively form a static random access memory (SRAM) cell with seven transistors.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a storage element formed of a first inverter and a second inverter cross-coupled to each other;
a first transistor having a first conductive type, and connected between a first bit line and a first storage node of the storage element;
a second transistor having the first conductive type, and connected between a second bit line and a second storage node of the storage element; and
a third transistor having a second conductive type opposite to the first conductive type, and connected between the first storage node and a third bit line.

2. The memory device of claim 1, wherein the first conductive type is p-type, and the second conductive type is n-type.

3. The memory device of claim 1, wherein the first transistor has a first gate terminal and the second transistor has a second gate terminal, and the first gate terminal and the second gate terminal are connected to a first word line.

4. The memory device of claim 3, wherein the third transistor has a third gate terminal connected to a second word line.

5. The memory device of claim 4, wherein when programming the storage element, the first word line is configured to be at a logic low state and the second word line is configured to be at the logic low state.

6. The memory device of claim 4, wherein when reading the storage element, the first word line is configured to be at a logic high state and the second word line is configured to be at the logic high state.

7. The memory device of claim 1, wherein the first bit line and the second bit line are configured to program the storage element.

8. The memory device of claim 1, wherein the third bit line is configured to read the storage element.

9. A memory device, comprising:
a memory cell consisting of a first transistor, a second transistor, a third transistor, a fourth transistor, a fifth transistor, a sixth transistor, and a seventh transistor, the memory cell configured to be read through a first bit line and a first word line, and programmed through a second bit line, a third bit line, and a second word line;
wherein the first to fourth transistors operatively form a pair of cross-coupled inverters to store a data bit with a first storage node and a second storage node;
wherein the fifth transistor and the sixth transistor are commonly gated by the second word line and respectively connected to the second bit line and the third bit line;
wherein the seventh transistor is gated by the first word line and connected to the first bit line; and
wherein the fifth transistor and the sixth transistor are configured in p-type, and the seventh transistor is configured in n-type.

10. The memory device of claim 9, wherein the fifth transistor is connected between the second bit line and the first storage node, and the sixth transistor is connected between the third bit line and the second storage node.

11. The memory device of claim 9, wherein the seventh transistor is connected between the first storage node and the first bit line.

12. The memory device of claim 9, wherein the first transistor and the second transistor operatively form a first one of the pair of inverters, with their respective gate terminals connected to the second storage node.

13. The memory device of claim 12, wherein the third transistor and the fourth transistor operatively form a second one of the pair of inverters, with their respective gate terminals connected to the first storage node.

14. The memory device of claim 9, wherein when programming the memory cell with the data bit, the second word line is configured to be at a logic low state and the first word line is configured to be at the logic low state.

15. The memory device of claim 9, wherein when reading the data bit from the memory cell, the second word line is configured to be at a logic high state and the first word line is configured to be at the logic high state.

16. The memory device of claim 9, wherein the memory cell is a static random access memory (SRAM) cell.

17. A method for forming a memory device, comprising:
forming a first active region extending along a first lateral direction with a first length, the first active region having a first conductive type;
forming a second active region extending along the first lateral direction with a second length and spaced from the first active region along a second lateral direction perpendicular to the first lateral direction, the second active region having a second conductive type, the second length longer than the first length; and
forming a first gate structure, a second gate structure, a third gate structure, a fourth gate structure, and a fifth gate structure, each of which extends along the second lateral direction, the first gate structure traversing the second active region, the second gate structure traversing both the first active region and the second active region, the third gate structure traversing both the first active region and the second active region, the fourth gate structure traversing the second active region, the fifth gate structure traversing the first active region;
wherein the first active region, the second active region, and the first to fifth gate structures are configured to collectively form a static random access memory (SRAM) cell with seven transistors.

18. The method of claim 17, wherein the first conductive type is n-type, and the second conductive type is p-type.

19. The method of claim 17, wherein the first active region includes a plurality of first nanostructures vertically spaced from one another, and the second active region includes a plurality of second nanostructures vertically spaced from one another.

20. The method of claim 17, wherein the first active region is formed in a first level and the second active region is formed in a second level vertically spaced from the first level.
